(19) United States
(12) Patent Application Publication
(10) Pub. No.: US 2013/0043502 A1
(43) Pub. Date: Feb. 21, 2013

(54) LIGHT EMITTING DEVICE AND METHOD FOR MANUFACTURING THE SAME

(71) Applicants: Kenichi Koya, Kagoshima (JP); Tadaaki Ikeda, Kagoshima (JP); Michio Miyawaki, Kagoshima (JP); Hiroki Utatsu, Kagoshima (JP)

(72) Inventors: Kenichi Koya, Kagoshima (JP); Tadaaki Ikeda, Kagoshima (JP); Michio Miyawaki, Kagoshima (JP); Hiroki Utatsu, Kagoshima (JP)

(73) Assignee: PANASONIC CORPORATION, Kadoma-shi, Osaka (JP)

(21) Appl. No.: 13/695,752

(22) PCT Filed: Mar. 26, 2011
(86) PCT No.: PCT/JP2011/002929

§ 371 Date: Nov. 1, 2012

(30) Foreign Application Priority Data
May 31, 2010 (JP) 2010-123981

(51) Int. Cl. H01L 33/62; H01L 33/60

(52) U.S. Cl. 257/98; 257/99; 438/27; 257/E33.056; 257/E33.068

(57) ABSTRACT

A light emitting device 10 includes a light emitting element 11, a package 13 in which the light emitting element 11 is accommodated, and a sealing member 14 configured to seal the light emitting element 11. The package 13 includes a base 13B configured to hold the light emitting element 11 and a frame part 13A vertically standing on the base 13B so as to surround the light emitting element 11. The sealing member 14 is embedded in a region surrounded by the frame part 13A. The frame part 13A includes a protruding wall 15 upwardly protruding from an upper end surface 132a of the frame part 13A and provided so as to surround the light emitting element 11.

### TECHNICAL FIELD

The present disclosure relates to a light emitting device and a method for manufacturing the light emitting device. In particular, the present disclosure relates to a light emitting device including a package in which a light emitting element is sealed.

### BACKGROUND ART

In a light emitting device, a sealing resin part configured to protect a light emitting element and a wire connected to the light emitting element and to form a lens part for converging or diverging light emitted from the light emitting element is provided.

For example, the following method has been known as a method for manufacturing a light emitting device including the foregoing sealing resin part (see, e.g., Patent Document 1). A chip-shaped semiconductor light emitting element etc. are accommodated in a light emitter accommodation member. After connection of a wire(s) etc., the light emitter accommodation member is filled with a sealing resin material. A lens formed by a mold in advance and having a raised surface which is to be a light focusing surface is placed on the applied sealing resin material with the raised surface facing the sealing resin material. The sealing resin material is cured by, e.g., heating, and, as a result, a light emitting device in which the lens is bonded onto the sealing resin part can be manufactured.

### CITATION LIST

### Patent Document

PATENT DOCUMENT 1: Japanese Patent Publication No. 2004-276383

### SUMMARY OF THE INVENTION

### Technical Problem

However, in a conventional light emitting device, since a lens is formed by a mold in advance and is bonded after sealing of a light emitting element etc. with resin, an extra step(s) are required. If an accommodation part can be filled with sealing resin such that the sealing resin part has a raised surface, a lens can be integrally formed with the sealing resin part.

As a general method for forming a sealing resin part, e.g., transfer molding or screen printing is used. If a light emitting element is arranged in an accommodation part of, e.g., a cup-shaped reflector or a box-shaped housing, potting is often used to fill the accommodation part with liquid resin. In the case of the potting for injecting liquid resin, it is likely that the amount of liquid resin to be dropped varies. When liquid resin is dropped such that a surface of the sealing resin part defines a raised surface or a recessed surface due to surface tension, the liquid resin may overflow from the accommodation part due to the variation in liquid resin amount. If the liquid resin overflows, there is a possibility that the liquid resin is adhered to an electrode etc. provided outside the accommodation part, and therefore contact fault may occur. This causes lower reliability.

It is an objective of the present disclosure to provide a high-reliability light emitting device in which, even if an accommodation part is filled with a sealing material for sealing a light emitting element by potting, the sealing material is less likely to overflow from the accommodation part, and to provide a method for manufacturing the light emitting device.

### Solution to the Problem

In order to accomplish the foregoing objective, a light emitting device of the present disclosure includes a frame part surrounding a light emitting element and a sealing member formed in a region surrounded by the frame part, and a protruding wall upwardly protruding from an upper end surface of the frame part is provided.

Specifically, an exemplary light emitting device includes a light emitting element; a package in which the light emitting element is accommodated; and a first sealing member configured to seal the light emitting element. The package includes a base for holding the light emitting element and a frame part vertically standing on the base so as to surround the light emitting element. A region surrounded by the frame part is filled with a material of the first sealing member. The frame part has a first protruding wall upwardly protruding from an upper end surface of the frame part and provided so as to surround the light emitting element.

Since the protruding wall is provided on the upper end surface of the frame part in the exemplary light emitting device, overflow of the material of the sealing member can be reduced, and a high-reliability light emitting device can be realized.

In the exemplary light emitting device, the first protruding wall may be formed so as to extend from an outer wall surface of the frame part.

In the exemplary light emitting device, the first protruding wall may be a burr formed when the frame part is molded from resin.

In the exemplary light emitting device, the upper surface of the frame part may be formed in a curved shape such that a height in a center part of the upper surface in a direction along a line connecting between an inner wall surface and an outer wall surface of the frame part is different from a height at both end parts of the upper surface.

In the exemplary light emitting device, the first sealing member may be formed so as to have a raised upper surface.

The exemplary light emitting device may further include a lead frame integrally formed with the package. The light emitting element may be fixed onto a principal surface of a die pad part of the lead frame.

The exemplary light emitting device may further include reflective plates provided respectively on both sides of the light emitting element so as to face each other, vertically standing on the principal surface of the die pad part, having a height lower than that of the frame part, and contacting an inner wall surface of the frame part at both end parts; and a second sealing member formed in a region surrounded by the reflective plates and the inner wall surface of the frame part. Each of the reflective plates may include a second protruding wall upwardly protruding from an upper end surface of the each of the reflective plates, and the second sealing member may contain a phosphor.

An exemplary method for manufacturing a light emitting device includes step (a) for forming a package in which a lead frame is embedded between a base and a frame part; step (b) for fixing a light emitting element onto a die pad part of the lead frame; and step (c) for applying, after the step (b), a material of a first sealing member to a region surrounded by the frame part. At the step (a), a first space surrounded by a first molding surface corresponding to an outer wall surface of the frame part, a second molding surface corresponding to an inner wall surface of the frame part, and a third molding surface corresponding to an upper end surface of the frame part is formed by first and second mold parts assembled together, and resin is applied into the first space. A first parting line between the first and second mold parts is positioned along the upper end surface of the frame part. A burr is formed at a position of the first parting line to form a first protruding wall upwardly protruding from the upper end surface of the frame part.

In the exemplary method, at the step (a), reflective plates provided respectively on both sides of the light emitting element so as to face each other, vertically standing on a principal surface of the die pad part, having a height lower than that of the frame part, and contacting the inner wall surface of the frame part at both end parts are formed together with the frame part. At the step (c), after a region surrounded by the reflective plates and the inner wall of the frame part is filled with a material of a second sealing member containing a phosphor, the material of the first sealing member is applied. The second mold part includes first and second parts, the first and second parts are assembled together to form a space in which each of the reflective plates is to be formed, and a second parting line between the first and second parts is positioned along an upper end surface of the each of the reflective plates. A burr is formed at a position of the second parting line to form a second protruding wall upwardly protruding from the upper end surface of the each of the reflective plates.

### Advantages of the Invention

In the light emitting device of the present disclosure, the protruding wall can stop the overflow of the material of the sealing member. Thus, a high-reliability light emitting device in which the material of the sealing member is less likely to overflow can be realized.

### BRIEF DESCRIPTION OF THE DRAWINGS

FIGS. 1(a)-1(e) illustrate a light emitting device of a first embodiment. FIG. 1(a) is a plan view. FIG. 1(b) is a front view. FIG. 1(c) is a bottom view. FIG. 1(d) is a left side view. FIG. 1(e) is a right side view.

FIGS. 2(a) and 2(b) illustrate the light emitting device of the first embodiment. FIG. 2(a) is a plan view. FIG. 2(b) is a cross-sectional view along an IIb-IIb line of FIG. 2(a).

FIG. 3 is a cross-sectional view illustrating one example of a mold assembly used for manufacturing the light emitting device of the first embodiment.

FIG. 4 is an enlarged cross-sectional view illustrating an upper end part of a frame part of the light emitting device of the first embodiment.

FIG. 5 is a cross-sectional view illustrating a variation of the mold assembly used for manufacturing the light emitting device of the first embodiment.

FIGS. 6(a) and 6(b) illustrate a light emitting device of a second embodiment. FIG. 6(a) is a plan view. FIG. 6(b) is a cross-sectional view along a VIb-VIb line of FIG. 6(a).

FIG. 7 is a cross-sectional view illustrating one example of a mold assembly used for manufacturing the light emitting device of the second embodiment.

### DESCRIPTION OF EMBODIMENTS

### First Embodiment

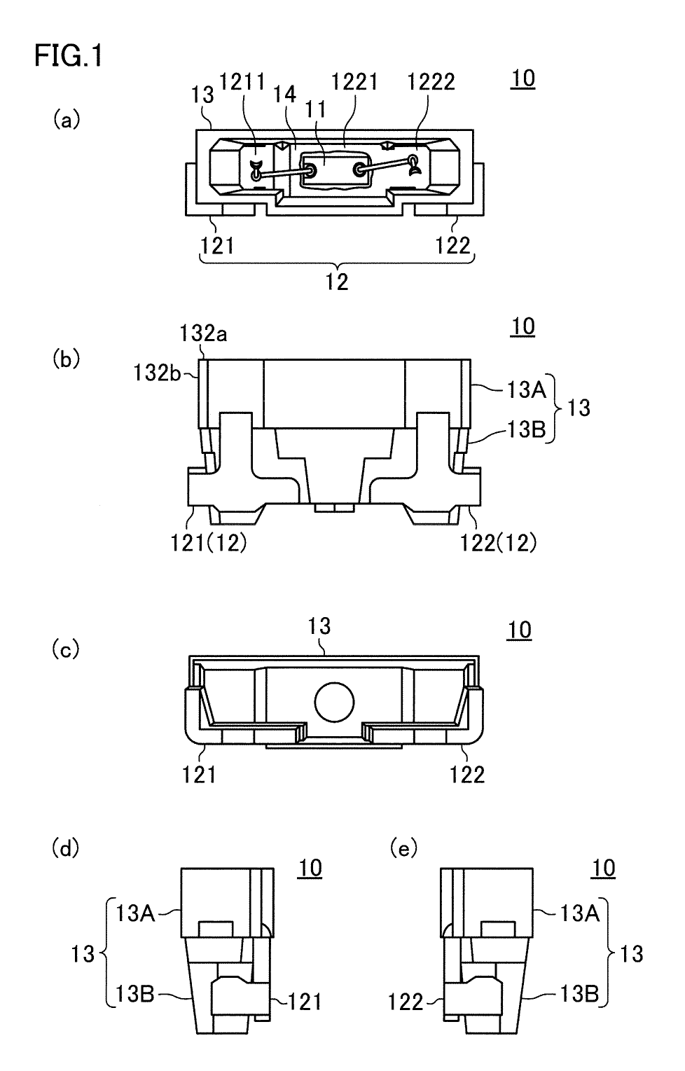

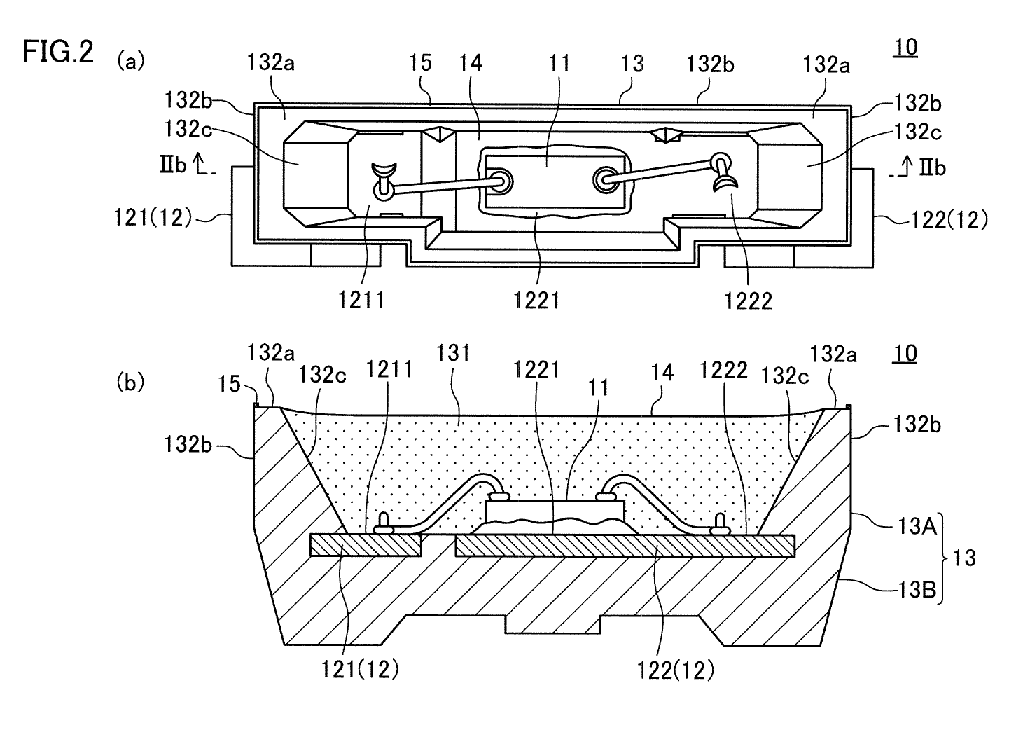

Referring to FIGS. 1 and 2, a light emitting device 10 of a first embodiment is a side-view type LED. The light emitting device 10 includes a light emitting element 11, a lead frame 12, a package 13, and a sealing member 14.

In the present embodiment, the light emitting device 10 is formed so as to have a height (from a lower end of the lead frame 12 to an upper end of the package 13) of about 2 mm, a width (i.e., the width of the package 13) of about 3 mm, and a thickness (i.e., the thickness of the package 13) of about 1 mm.

The light emitting element 11 is, e.g., a light emitting diode functioning as a point light source formed in a rectangular shaped as viewed in the plane. The light emitting element 11 may be configured as follows: an n-type semiconductor layer, a light emitting layer, and a p-type semiconductor layer are stacked in this order on an insulating substrate; a p-side electrode is formed on the p-type semiconductor layer; and an n-side electrode is formed on part of the n-type semiconductor layer exposed by etching. The substrate of the light emitting element 11 is die-bonded to the lead frame 12 with the n-side electrode and the p-side electrode facing up.

The lead frame 12 may be a copper alloy plate formed by stacking plating layers made of, e.g., nickel or gold and patterning the plating layers. The lead frame 12 includes an anode frame 121 and a cathode frame 122. In the anode frame 121, a first wire bonding part 1211 to which a wire from the light emitting element 11 is bonded is formed. In the cathode frame 122, the followings are formed: a die bonding part 1221 on which the light emitting element 11 is mounted; and a second wire bonding part 1222 to which a wire from the light emitting element 11 is bonded. The light emitting element 11 is fixed onto a first surface of the die bonding part 1221.

The package 13 is integrally formed with the lead frame 12 such that the lead frame 12 is embedded in the package 13. The package 13 includes a base 13B for holding the lead frame 12 from a side closer to a second surface which is opposite to the first surface to which the light emitting element 11 is fixed, and a frame part 13A provided so as to surround the light emitting element 11 and vertically stand on the base 13B.

Each of the anode frame 121 and the cathode frame 122 outwardly protrudes, at each end part thereof, beyond an outer wall surface of the frame part 13A. Each of the end parts of the anode frame 121 and the cathode frame 122 protruding beyond the package 13 is bent along the side of the base 13B. Each of the end parts of the anode frame 121 and the cathode frame 122 bent along the side of the base 13B is in a T shape. Each of the T-shaped parts extends along a long side of the package 13 at one end, and reaches a middle part of a short side of the package 13 at the other end.

A recess (accommodation part) 131 surrounded by the frame part 13A of the package 13 is filled with a material, e.g., resin, of the sealing member 14. After the recess 131 is filled with thermoset or thermoplastic liquid resin by potting, the liquid resin may be cured by heat to form the sealing member 14. As the liquid resin, e.g., silicon resin, epoxy resin, or fluorine resin may be used. The sealing member 14 may contain a phosphor excited by light from the light emitting element 11 to emit light. For example, in the case where the light emitting element 11 is a blue light emitting diode, if the sealing member 14 contains a phosphor absorbing blue light and excited by the blue light to emit yellow light having a complementary color for blue, the blue light and the yellow light are mixed into white light.

On an upper end surface 132a of the frame part 13A, a protruding wall 15 (not shown in FIG. 1) upwardly protruding from the upper end surface 132a is formed. The protruding wall 15 has a height of about 5-20 μm, and is formed along an outer edge of the frame part 13A as viewed in FIG. 2. The protruding wall 15 may be a burr formed when the package 13 is molded.

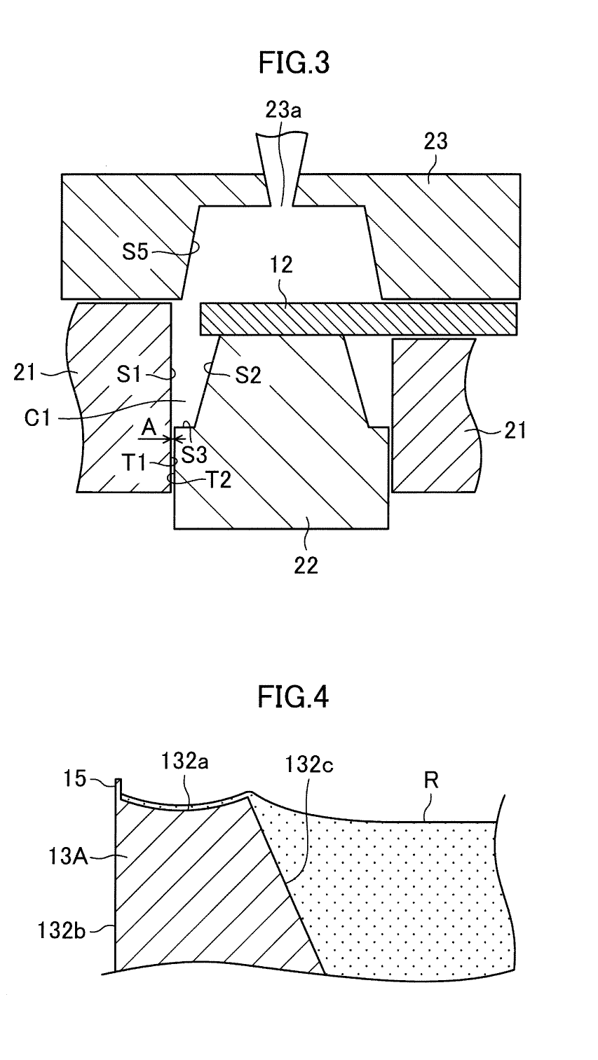

A method for forming the protruding wall 15 will be described with reference to FIG. 3. Referring to FIG. 3, the package 13 is formed by using a mold assembly including a first mold part (lower mold part) 21, a second mold part (core pin) 22, and a third mold part (upper mold part) 23 which are assembled together with the lead frame 12 being sandwiched thereby. The first mold part 21 has a molding surface S1 corresponding to an outer wall surface 132b of the frame part 13A. The second mold part 22 has a molding surface S2 corresponding to an inner wall surface 132c of the frame part 13A and a molding surface S3 corresponding to an upper end surface 132a. The third mold part 23 has a molding surface S5 corresponding to an outer wall surface of the base 13B. In the third mold part 23, an injection port 23a through which liquid resin is injected is provided.

The first to third mold parts 21-23 assembled as described above are clamped with the lead frame 12 being sandwiched by the first to third mold parts 21-23, and a cavity is filled with liquid resin injected through the injection port 23a. Then, the injected liquid resin is cured, and the first to third mold parts 21-23 are disassembled from each other. As a result, the package 13 is molded. The frame part 13A is made of resin injected to a space C1 surrounded by the molding surfaces S1-S3.

The molding surface S1 of the first mold part 21 is formed in a flat shape, and is flush with a contact surface T1. The contact surface T1 contacts a contact surface T2 of the third mold part 23, and the contact surfaces T1, T2 define a parting surface which is a mating surface of the mold parts. Thus, a parting line is positioned along an outer edge of the upper end surface 132a of the frame part 13A. After the cavity is filled with liquid resin, the resin enters a clearance A between the contact surface T1 of the first mold part 21 and the contact surface T2 of the third mold part 23, and a burr is formed at the position of the parting line. The clearance A is adjusted to control, e.g., the height and thickness of the burr. In the foregoing manner, the protruding wall 15 can be formed in an outer end part of the upper end surface 132a of the frame part 13A.

Next, formation of the sealing member 14 will be described. Referring to FIG. 2, after the package 13 is integrally molded with the lead frame 12 by using the first to third mold parts 21-23, the light emitting element 11 is mounted on the die bonding part 1221, and the wires from the light emitting element 11 are connected respectively to the first wire bonding part 1211 and the second wire bonding part 1222. Subsequently, the recess 131 is, by potting, filled with liquid resin to be formed into the sealing member 14.

Typically, when the recess 131 is filled with liquid resin, the amount of liquid resin is adjusted, considering the surface tension, such that an upper surface of the sealing member 14 defines a recessed surface and an edge part of the sealing member 14 reaches an upper end of the frame part 13A. However, since the amount of liquid resin to be dropped widely varies, there is a possibility that the liquid resin overflows from the recess 131 beyond the upper end surface 132a of the frame part 13A. A semiconductor device of the present embodiment includes the protruding wall 15 on the upper end surface 132a of the frame part 13A. Thus, liquid resin flowing along the upper end surface 132a can be blocked by the protruding wall 15 upwardly protruding from the upper end surface 132a, and therefore overflow of the liquid resin can be prevented. Particularly in order to form the raised upper surface of the sealing member 14, it is necessary to increase the amount of liquid resin. In such a case, a great advantage of providing the protruding wall 15 can be realized.

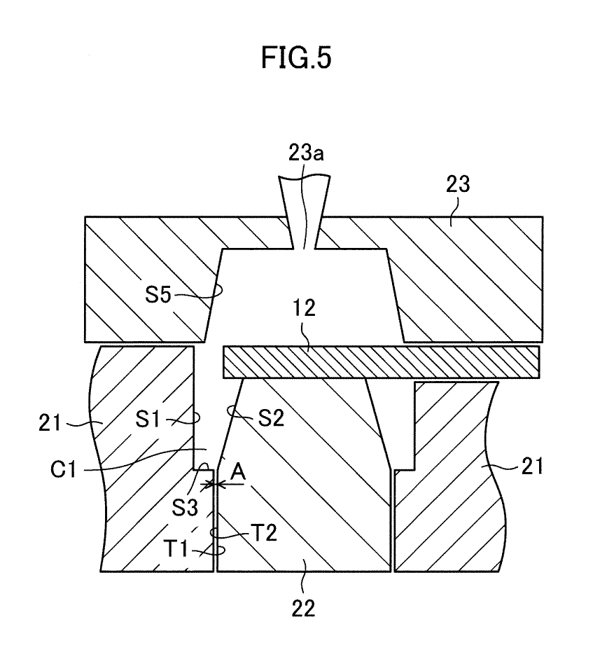

If the upper end surface 132a of the frame part 13A is, referring to FIG. 4, in a recessed curved shape in which a center part of the upper end surface 132a of the frame part 13A in a direction along a line connecting between the inner wall surface 132c and the outer wall surface 132b is positioned lower than both end parts of the upper end surface 132a of the frame part 13A, the flow distance of liquid resin R along the upper end surface 132a can be increased as compared to the case where the upper end surface 132a is in a flat shape. Thus, as compared to the case where the upper end surface 132a is in a flat shape, the liquid resin R is less likely to reach the protruding wall 15 and to overflow.

In the present embodiment, the upper end surface 132a is formed in a recessed shape by using contraction of resin. However, by using a second mold part 22 having a raised molding surface S3, the upper end surface 132a may be formed in a recessed shape. Alternatively, by using a second mold part 22 having a recessed molding surface S3, the upper end surface 132a may be formed in a raised curved shape. In such a case, the liquid resin R to be formed into the sealing member is less likely to overflow.

Although the case where the protruding wall 15 is formed in the outer end part of the frame part 13A has been described, the protruding wall 15 may be formed in an inner end part of the frame part 13A. If the protruding wall 15 is formed in the inner end part, the molding surface S3 corresponding to the upper end surface 132a of the frame part 13A may be, referring to, e.g., FIG. 5, formed in the first mold part 21, and the contact surface T1 of the first mold part 21 and the contact surface T2 of the second mold part 22 may contact each other on a side closer to the molding surface S2 corresponding to the inner wall surface 132c. That is, the parting line between the first mold part 21 and the second mold part 22 may be along an inner end of the upper end surface 132a. Alternatively, the protruding wall 15 may be provided in the center part of the upper end surface 132a in the following manner: the contact surface T1 of the first mold part 21 and the contact surface T2 of the second mold part 22 are arranged so as to contact each other at the middle of the molding surface S3 corresponding to the upper end surface 132a of the frame part 13A, and the parting line is positioned in the center part of the upper end surface 132a.

### Second Embodiment

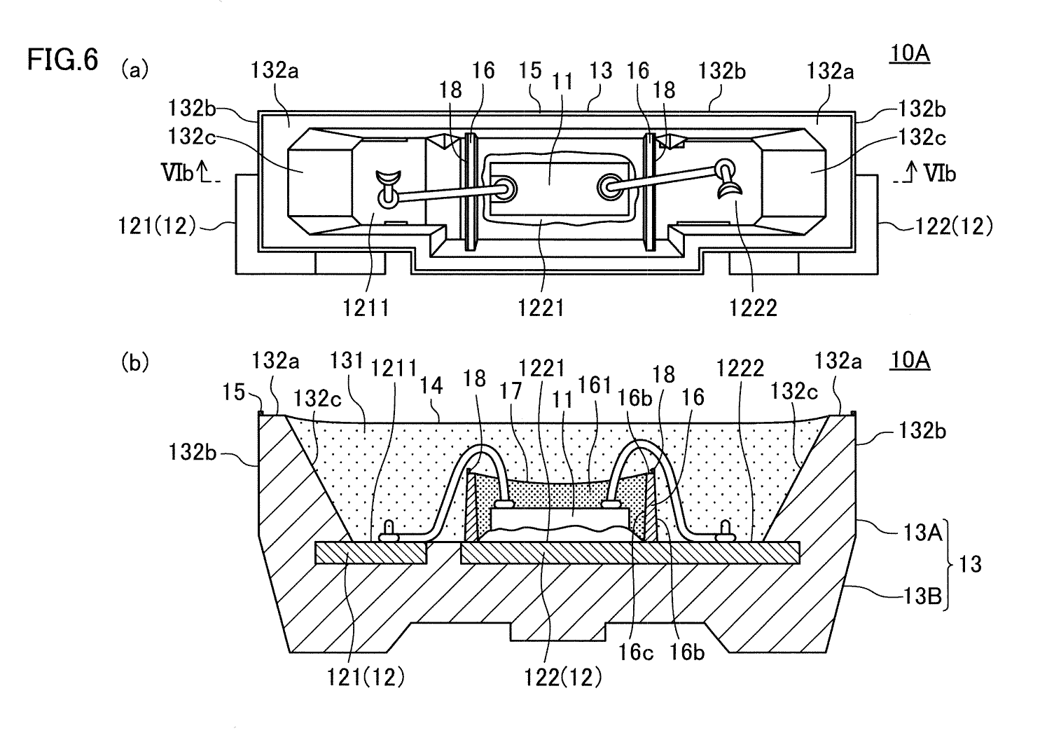

FIG. 6 illustrates a light emitting device of a second embodiment. A light emitting device 10A of the second embodiment is different from the light emitting device 10 of the first embodiment in that the light emitting device 10A includes reflective plates 16.

Referring to FIG. 6, the reflective plates 16 stand, on both sides of a light emitting element 11, vertically on a first surface of a cathode frame 122 so as to face each other. The height of the reflective plate 16 is lower than that of a frame part 13A, and a side end part of the reflective plate 16 contacts an inner wall surface of the frame part 13A. A recess 161 surrounded by the reflective plates 16 and the frame part 13A is filled with a material, e.g., sealing resin containing a phosphor, of a sealing member 17. A recess surrounded by the frame part 13A is filled with a material, e.g., transparent sealing resin, of a sealing member 14 such that the sealing member 14 covers the sealing member 17.

The reflective plates 16 are provided, and only the recess 161 surrounded by the reflective plates 16 is filled with the sealing resin containing the phosphor. Thus, the wavelength of light emitted from a light emitting element can be converted, and the light can exit in an upward direction. Consequently, the light emitting element can be used not as an element emitting diffusion light but as a point light source. However, if the liquid resin containing the phosphor overflows from the recess 161, the phosphor overflowing from the recess 161 is excited by light reflected by, e.g., the transparent resin, and light conversion occurs in an unintended part. Thus, there is a possibility that color unevenness occurs. In addition, the sealing member 17 overflowing from the recess 161 may cause peeling of the sealing member 17 itself, and may cause peeling of the sealing member 14. Further, there is a possibility that the liquid resin is adhered to a first wire bonding part 1211 and a second wire bonding part 1222, resulting in lower reliability of the light emitting device.

However, in the present embodiment, a protruding wall 18 upwardly protruding along an outer wall of the reflective plate 16 is formed on each of upper surfaces 16a of the reflective plates 16. The protruding walls 18 are provided respectively on the upper surfaces 16a of the reflective plates 16 so as to face each other. Thus, when the sealing member 17 is formed, the sealing resin containing the phosphor can be prevented from overflowing from the recess 161, and therefore light emission properties and reliability of the light emitting device can be improved.

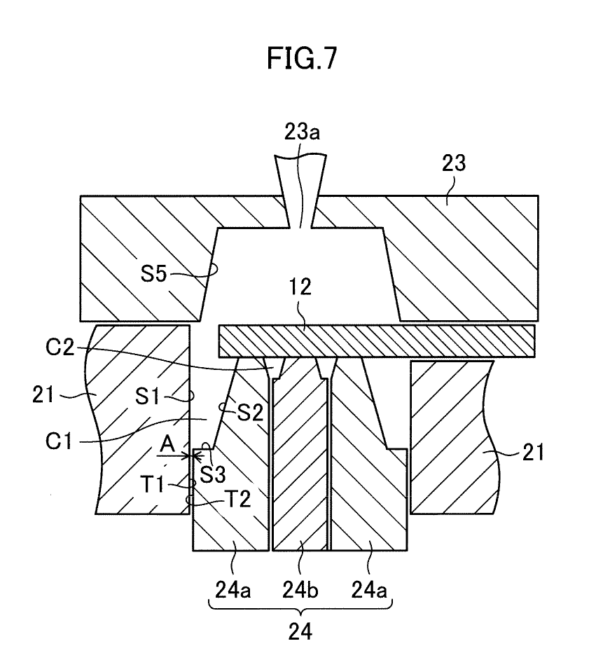

A method for forming the reflective plates 16 and the protruding walls 18 will be described with reference to FIG. 7. Referring to FIG. 7, the reflective plates 16 and a package 13 are formed by using a first mold part (lower mold part) 21, a second mold part (core pin) 24, and a third mold part (upper mold part) 23 which are assembled together with a lead frame 12 being sandwiched thereby. As in the first embodiment, the frame part 13A including the protruding wall 15 is formed by the first mold part 21 and the second mold part 24. In addition, in the present embodiment, the second mold part 24 includes a pair of outer core pins 24a and a center core pin 24b sandwiched between the outer core pins 24a. A space (cavities) C2 in which the reflective plate 16 is formed is formed by each of the outer core pins 24a and the center core pin 24b. If a parting line between the outer core pin 24a and the center core pin 24b is positioned above the upper surface 16a of the reflective plate 16, the protruding wall 18 which is similar to the protruding wall 15 of the frame part 13A can be formed on the upper surface 16a of the reflective plate 16. Although the position of the parting line is at an outer end of the upper surface 16a of the reflective plate 16 in FIG. 7, the position of the parting line may be at an inner end of the upper surface 16a of the reflective plate 16 or in a center part of the upper surface 16a of the reflective plate 16.

The recess 161 formed by the reflective plates 16 and the frame part 13A is, by potting, filled with liquid resin containing a phosphor. When an excessive amount of liquid resin is injected, there is a possibility that the liquid resin injected to the recess 161 overflows from the recess 161 beyond the upper surface 16a of the reflective plate 16. However, in the present embodiment, even if the amount of liquid resin to be injected varies, the protruding walls 18 can stop the liquid resin from flowing beyond the upper surfaces 16a of the reflective plates 16.

After the recess 161 is filled with a material of the sealing member 17 containing a phosphor, the material of the sealing member 17 is cured, and then the recess 131 is filled with a transparent material of the sealing member 14. Thus, the material of the sealing member 17 and the material of the sealing member 14 are not mixed together. The sealing member 14 may contain a phosphor different from that of the sealing member 17.

The case where the recess 161 is filled with the liquid resin containing the phosphor has been described. However, if light emitted from the light emitting element 11 is used without light conversion, the recess 161 may be filled with liquid resin which does not contain a phosphor.

Although the case where the protruding wall 18 is formed at the outer end of the upper surface 16a has been described in the present embodiment, the protruding wall 18 may be formed at the inner end of the upper surface 16a. Alternatively, the protruding wall 18 may be formed in the center part of the upper surface 16a. The protruding wall 15 may be formed at an inner end of the frame part 13A or in a center part of the frame part 13A.

Although the case where the liquid resin is applied has been described in the first and second embodiments, liquid inorganic material may be applied.

### INDUSTRIAL APPLICABILITY

The high-reliability light emitting device in which the material of the sealing member for sealing the light emitting element is less likely to overflow from the accommodation part even if the accommodation part is filled with the material of the sealing member by potting, and the method for manufacturing the light emitting device can be realized. The light emitting device and the manufacturing method of the present disclosure are useful for, e.g., a light emitting device in which a light emitting element is sealed in a package and a method for manufacturing such a light emitting device.

### DESCRIPTION OF REFERENCE CHARACTERS

10 Light Emitting Device
10A Light Emitting Device
11 Light Emitting Element
12 Lead Frame
13 Package
13A Frame Part
13B Base
14 Sealing Member
15 Protruding Wall
16 Reflective Plate
16a Upper End Surface
17 Sealing Member
18 Protruding Wall
21 First Mold Part
22 Second Mold Part
23 Third Mold Part
23a Injection Port
24 Second Mold Part
24a Outer Core Pin
24b Center Core Pin
121 Anode Frame
122 Cathode Frame
131 Recess
132a Upper End Surface
132b Outer Wall Surface
132c Inner Wall Surface
161 Recess
1211 First Wire Bonding Part
1221 Die Bonding Part
1222 Second Wire Bonding Part

1. A light emitting device comprising:
a light emitting element;
a package in which the light emitting element is accommodated; and
a first sealing member configured to seal the light emitting element,
wherein the package includes a base for holding the light emitting element and a frame part vertically standing on the base so as to surround the light emitting element,
a region surrounded by the frame part is filled with a material of the first sealing member, and
the frame part has a first protruding wall upwardly protruding from an upper end surface of the frame part and provided so as to surround the light emitting element.

2. The light emitting device of claim 1, wherein
the first protruding wall is formed so as to extend from an outer wall surface of the frame part.

3. The light emitting device of claim 1, wherein
the first protruding wall is a burr formed when the frame part is molded from resin.

4. The light emitting device of claim 1, wherein
the upper surface of the frame part is formed in a curved shape such that a height in a center part of the upper surface in a direction along a line connecting between an inner wall surface and an outer wall surface of the frame part is different from a height at both end parts of the upper surface.

5. The light emitting device of claim 1, wherein
the first sealing member is formed so as to have a raised upper surface.

6. The light emitting device of claim 1, further comprising:
a lead frame integrally formed with the package,
wherein the light emitting element is fixed onto a principal surface of a die pad part of the lead frame.

7. The light emitting device of claim 6, further comprising:
reflective plates provided respectively on both sides of the light emitting element so as to face each other, vertically standing on the principal surface of the die pad part, having a height lower than that of the frame part, and contacting an inner wall surface of the frame part at both end parts; and
a second sealing member formed in a region surrounded by the reflective plates and the inner wall surface of the frame part,
wherein each of the reflective plates includes a second protruding wall upwardly protruding from an upper end surface of the each of the reflective plates, and
the second sealing member contains a phosphor.

8. A method for manufacturing a light emitting device, comprising:
step (a) for forming a package in which a lead frame is embedded between a base and a frame part;
step (b) for fixing a light emitting element onto a die pad part of the lead frame; and
step (c) for applying, after the step (b), a material of a first sealing member to a region surrounded by the frame part,
wherein, at the step (a), a first space surrounded by a first molding surface corresponding to an outer wall surface of the frame part, a second molding surface corresponding to an inner wall surface of the frame part, and a third molding surface corresponding to an upper end surface of the frame part is formed by first and second mold parts assembled together, and resin is applied into the first space,
a first parting line between the first and second mold parts is positioned along the upper end surface of the frame part, and
a burr is formed at a position of the first parting line to form a first protruding wall upwardly protruding from the upper end surface of the frame part.

9. The method of claim 8, wherein
at the step (a), reflective plates provided respectively on both sides of the light emitting element so as to face each other, vertically standing on a principal surface of the die pad part, having a height lower than that of the frame part, and contacting the inner wall surface of the frame part at both end parts are formed together with the frame part,
at the step (c), after a region surrounded by the reflective plates and the inner wall of the frame part is filled with a material of a second sealing member containing a phosphor, the material of the first sealing member is applied,
the second mold part includes first and second parts, the first and second parts are assembled together to form a space in which each of the reflective plates is to be formed, and a second parting line between the first and second parts is positioned along an upper end surface of the each of the reflective plates, and
a burr is formed at a position of the second parting line to form a second protruding wall upwardly protruding from the upper end surface of the each of the reflective plates.
